(19) United States
(12) Patent Application Publication
(10) Pub. No.: US 2013/0009032 A1
(43) Pub. Date: Jan. 10, 2013

(54) SUPPORT STAND WITH FLEXIBLE CONNECTORS FOR OBJECTS, PORTABLE ELECTRONIC DEVICES, MUSICAL EQUIPMENT, CLIPBOARDS, ETC., USING STANDARD MICROPHONE HOLDER, HORIZONTAL SURFACE OR WALL MOUNT

(75) Inventors: Gregory Polletta, Waterbury, CT (US); Sung Bae Jang, Itasca, IL (US)

(73) Assignees: SUNG BAE JANG, Itasca, IL (US); GREGORY N. POLLETTA, Waterbury, CT (US)

(21) Appl. No.: 13/175,911

(22) Filed: Jul. 4, 2011

(51) Int. Cl. H05K 7/00

(52) U.S. Cl. 248/440.1; 248/176.3

(57) ABSTRACT

The present invention provides a portable support stand for various devices such as computers, tablet PCs, electronic equipment, clipboards, tools, etc. The stand uses a uni-pod configuration promoting stability of the attached device. The leg of the uni-pod may be stationary or adjustable for height and viewing angle. An audible indicator may be used to allow the user to know adjustment is occurring. Objects are attached to the uni-pod leg via elastic straps and adjustable for length and secured inside the uni-pod leg forming a secure slip free connection with the object. A non-slip cap sits between the object attached and the uni-pod leg. A second non-slip tip is attached to the end of the leg to prevent slipping. The uni-pod leg is of a specific diameter and size as to be used with standard microphone stands providing a secure hold on objects via a standard microphone stand clip.

### CROSS REFERENCE TO RELATED APPLICATIONS

This application has no continuations from any other filed or pending U.S. patent application

### BACKGROUND OF THE INVENTION

In accordance with an embodiment of the present invention, a portable support stand for supporting laptop computers, clipboards, tablet PCs, musical equipment, is provided. The stand comprises a primary support leg with non slip primary support leg tip, a center adjustment ring, internal rotation ratchet, elastic connector bands, and a non slip cap. The primary support leg is an elongated body acting as a pivot member. The elongated body includes a non slip primary support leg tip for contacting a support surface (horizontal or vertical) and a second end remote from the first end. The primary support leg pivot member is disposed perpendicular to the center adjustment ring. The center adjustment ring is rotatably coupled to the primary support leg member thereof. The primary support leg is operable to move between a compact position in which the respective main body is substantially received within the receptacle of the center adjustment ring, as shown in FIGS. 5A-5C. Furthermore, any Laptop computers, book, tablet PCs, musical equipment is securely fastened to the center adjustment ring by a series of 2 or more elastic connector bands FIG. 8a-8c allowing for the securing of said device or book to the present invention. The elastic connector bands clip internally to the inner portion of the center adjustment ring as shown in FIG. 5C via internal elastic connector tabs as shown in FIG. 9 jointly and in a snug position parallel to the front surface of the present invention as shown in FIGS. 1A-1E; 2A-2E; 2A-3E; 4A-4E. The present invention comes in contact with laptops, computers, clipboards, tablet PCs, musical equipment at the non slip cap as shown in FIG. 5C and specifically FIG. 10.

The main body of the device FIG. 7. has a tapered diameter similar to that of an industry standard support apparatus for musical microphones as shown in FIG. 13 similar to U.S. Design patent application Ser. No. US D618,222S filed on Jan. 22, 2009 and entitled “EQUIPMENT STAND” and U.S. Design patent Ser. No. D579,928S, filed on Oct. 11, 2007 “MICROPHONE HOLDER.” Neither of these designs Ser. No. US D618,222S or Ser. No. D579,928S are claims in this patent and referenced here to show that our device utilizes these industry standard microphone holding diameters to secure our device to standard microphone stands if so desired by the end user.

In one alternative, the portable support stand allows for the rotation and positioning of any object placed within it and resting on a horizontal or vertical surface as shown in FIGS. 1A-1E; 2A-2E; 2A-3E; 4A-4E.

In another alternative, objects are secured from slipping or via vibration where the object comes in contact with the stand when substantially parallel to the front of the invention and touching the non slip cap which is secured to the center adjustment ring by a series of non slip cap connector tabs FIG. 10.

In another alternative, any sized object may be placed on the stand and secured via the elastic connector bands as shown in FIGS. 8A-8C regardless of the shape or size of the object respective to the center body non slip cap where the device is attached if substantially parallel to the front of the as shown in FIGS. 1E,2E,3E,4E.

In another alternative, the primary support leg and pivot member includes a first engagement to the center adjustment ring to lock the adjustable primary support leg and to permit movement between the upright and angled positions on a horizontal or vertical surface as shown in FIGS. 14-17, or via a microphone stand as shown in FIG. 13

In a further alternative, the primary pivot member primary support leg internal rotational clips in conjunction with the internal rotational ratchet and internal ratchet selectors via the center adjustment ring provides a means for producing an audible indicator to identify when the adjustable primary support leg is changing position or orientation or angle as shown in FIGS. 14,15,16,17.

In a further alternative, each of the multiple elastic connector bands provide a connection to the center adjustment ring FIG. 9 by means of internal elastic connector tabs through any number of center adjustment ring elastic connector entry holes FIG. 12 at various positions in center adjustment ring mechanism to the multiple elastic connector bands FIG. 8a and their respective elastic connector holes FIG. 8b to be hidden from view only showing to the user the primary support leg and the multiple elastic connector bands as seen in FIG. 5A.

[RELATED TO CLAIM: Elastic bands, holes in the bands and their connection to

In another alternative, the plurality of the primary support leg is desirably distributed in a perpendicular arrangement about the center adjustment ring at FIG. 9 and comprised at least of one projection FIG. 7 operable to reasonably engage the center adjustment ring via the internal rotational ratchet FIG. 12 and the primary support leg internal rotational clips with at least one respective connection as shown in FIG. 11 utilizing the internal ratchet selectors.

In yet another alternative, the portable support stand further comprises a stopper member or non-slip primary support leg tip FIG. 6 coupled to the primary support leg FIG. 7.

In yet another alternative, the portable support stand further comprises a stopper member or non-slip primary support leg tip FIG. 6 that can rotate along the axis of primary support leg when the stand is positioned to grip a horizontal surface.

In one example, the electronic device, book, musical device., etc., is operable to act in a uni-pod configuration with the primary support leg and rear facing non-slip primary support leg tip on a horizontal surface and when secured to the perpendicular surface of an object via the non slip cap with the elastic connector bands wrapped around the edges of an object being held in the device thus creating two additional points of contact via the elastic connector bands and the primary support leg plus on a horizontal surface forming a tri-pod arrangement as seen in FIGS. 1a,1c,1e,2a,2c,2d,2e,3a,3c,3d,3e,4a,4c,4d,4e,

In accordance with a further embodiment of the present invention, a portable support stand for use with an electronic devices, clipboards, and musical devices comprises a primary support leg with a specific diameter FIG. 13 to be used with industry standard microphone clips and stands via an elongated body including a first end for contacting a support surface and a second end remote from the first end. The adjusting of height and angle of the stand is created by rotating the position of the primary support leg relative to the horizontal or vertical or free form surface so that the center adjustment ring and configured in either a 180.degree or 10.degree position and in contact of the support surface.

### BRIEF DESCRIPTION OF THE DRAWINGS

The present invention will hereinafter be described in conjunction with the appended drawing figures wherein like numerals denote like elements.

FIGS. 1A-1E illustrate a stand device supporting a tablet computer in accordance with aspects of the present invention.

FIGS. 2A-2E illustrate the stand device of FIGS. 1A-1F supporting a book in accordance with aspects of the present invention.

FIGS. 3A-3E illustrate the stand device of FIGS. 1A-1F supporting a laptop PC in accordance with aspects of the present invention.

FIGS. 4A-4E illustrate the stand device of FIGS. 1A-1F supporting a musical device in accordance with aspects of the present invention.

FIGS. 5A-5B illustrate a portable stand with the elastic connector bands in an open and closed configuration in accordance with aspects of the present invention.

FIG. 5C illustrates an exploded view of the portable stand of FIGS. 3A-3F in accordance with aspects of the present invention.

FIG. 6 illustrates the non-slip primary support leg tip of the portable stand of FIG. 5c in accordance with aspects of the present invention.

FIG. 7 illustrates the primary support leg—primary pivot member of the portable stand of FIG. 5c in accordance with aspects of the present invention.

FIGS. 8A-8B illustrates elastic connector bands and elastic connector holes in FIG. 5c in accordance with aspects of the present invention.

FIG. 9 illustrates the center adjustment ring of the stand in FIG. 5c in accordance with aspects of the present invention.

FIG. 10 illustrates the non slip cap in FIG. 5a in accordance with aspects of the present invention.

FIG. 11 illustrates the inner rotation ratchet of the primary support leg—primary pivot member of the stand in FIG. 5c in accordance with aspects of the present invention.

FIG. 12 illustrates the inner ratchet of the a rotating center adjustment ring, of the stand in FIG. 5c in accordance with aspects of the present invention.

FIG. 13 illustrates the portable stand of FIGS. 3A-3F in a compact configuration for use with an industry standard music stand clip as illustrated in FIGS. 1A-1E, FIGS. 2A-2E, FIGS. 3A-3E and FIGS. 4A-4E in accordance with aspects of the present invention.

FIG. 14 illustrate exemplary compact positioning of a stand from FIG. 1F in accordance with all aspects of the present invention.

FIG. 15 illustrate exemplary compact positioning of a stand from FIG. 1F in accordance with all aspects of the present invention.

FIG. 16 illustrate exemplary compact positioning of a stand from FIG. 1F in accordance with all aspects of the present invention.

FIG. 17 illustrate exemplary compact positioning of a stand from FIG. 1F in accordance with all aspects of the present invention.

FIG. 18 illustrates the internal rotational ratchet of FIG. 12 and the configuration used to secure to the primary support leg to the center adjustment ring via the internal ratchet selectors, the internal rotational ratchet, and the primary support leg internal rotational clips from FIG. 11

FIG. 19 illustrates the internal rotational ratchet of FIG. 12 as a cutaway drawing example used to further illustrate the above description.

### DETAILED DESCRIPTION OF THE PREFERRED EMBODIMENTS

The aspects, features and advantages of the present invention will be appreciated when considered with reference to the following description of preferred embodiments and accompanying figures. In describing the preferred embodiments of the invention illustrated in the figures, specific terminology will be used for the sake of clarity. However, the invention is not intended to be limited to the specific terms so selected, and it is to be understood that each term selected includes all technical equivalents that operate in a similar manner to accomplish a similar purpose. (standard—don't change)

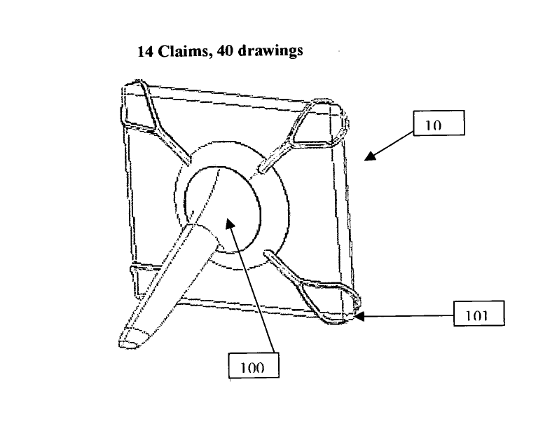

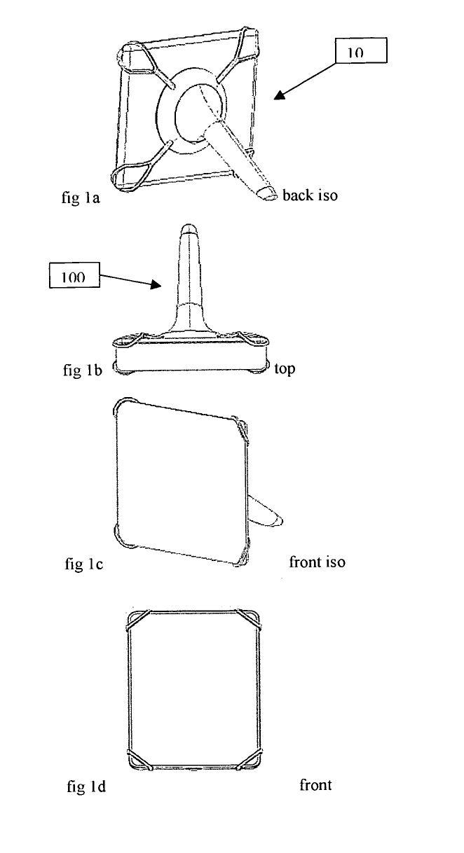

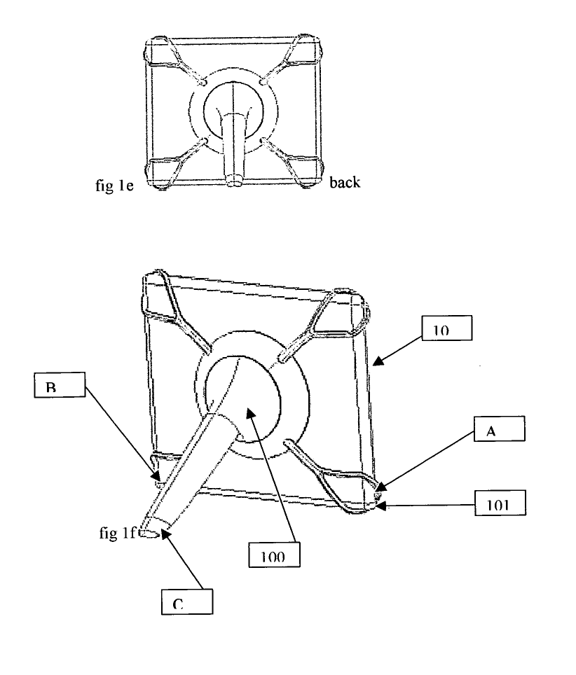

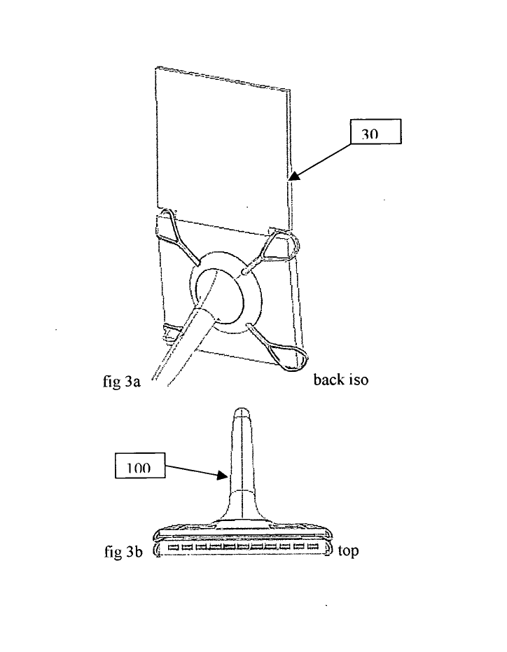

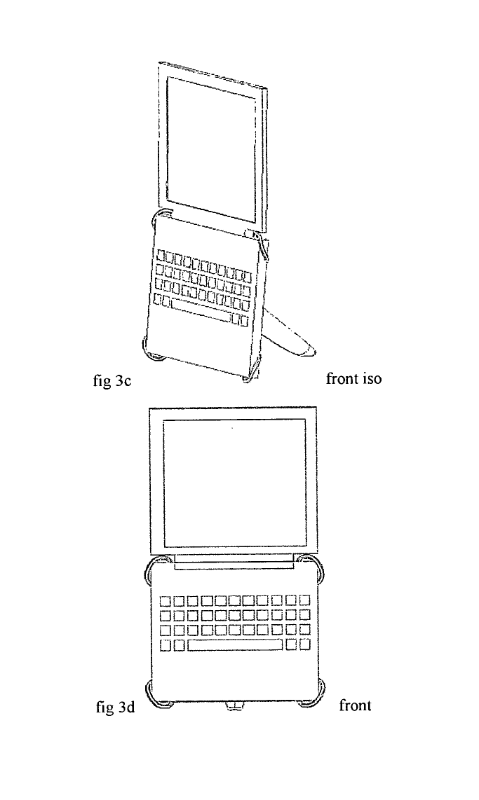

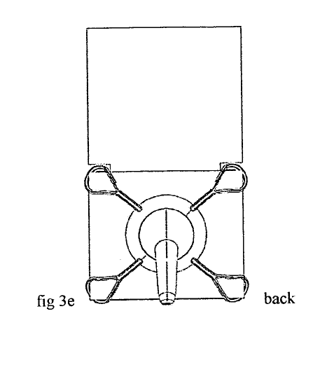

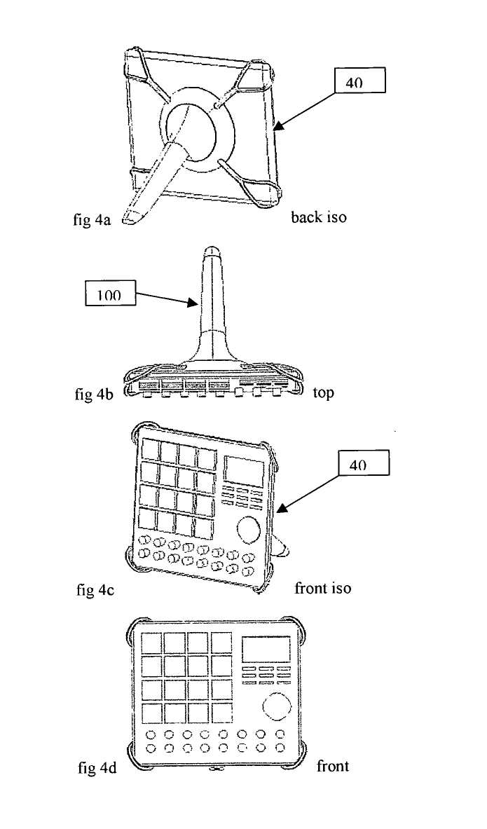

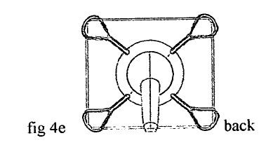

As mentioned above, the present invention provides a portable support platform or stand that is suitable for use with laptop computers, tablet computers and other portable equipment. FIGS. 1A-1E illustrate a tablet PC computer 10 that is supported by a stand 100. FIGS. 3A-3E illustrate the stand 100 supporting a laptop style personal computer (“laptop PC”) 20. 4A-4E illustrate the stand 100 supporting a musical device (“musical device”) 40. As can be seen in the various views of FIGS. 1 and 3 and 4, the stand 100 has a mono-pod-type configuration, which, as will be explained in more detail below, may be placed on many different surfaces in a wide variety of orientations and positions. This gives the user supreme flexibility in placing his or her laptop computer, tablet PC or other device in the exact arrangement desired. While the tablet PC 10 and laptop PC 30 and musical device 40 are exemplary, the stand 100 may support portable devices of many different types and configurations, including but not limited to PDAs, personal stereos, pictures, etc.

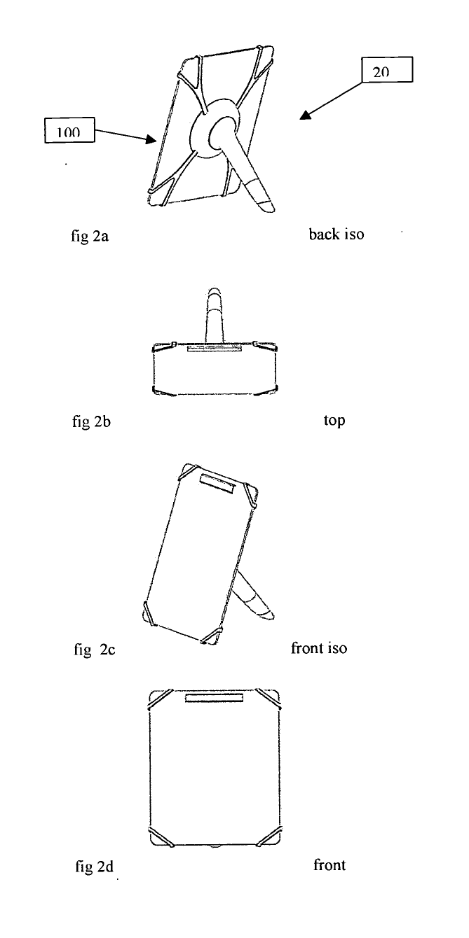

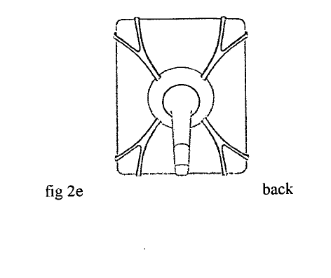

FIGS. 1A-1E illustrate the stand 100 in detail. As seen in the front and rear perspective views of FIGS. 1A and 1B, the stand 100 includes at a minimum a pair of elastic connector bands 103 that are coupled to the center adjustment ring 104 which enables the stand 100 to accommodate devices of varying sizes and shapes. Furthermore, the primary support leg 101 may adjusted at various angles, which is particularly helpful when positioning the laptop or tablet PC for viewing. Thus, it can be seen in FIG. 1F that the stand 100 preferably provides a rubber band and uni-pod configuration in which the stand rests on three points when placed on a support surface and also provides three points on which the user device rests. This rubber band and uni-pod arrangement is maintained no matter what specific placement is used to support the user device, as shown in the examples of FIGS. 1-4

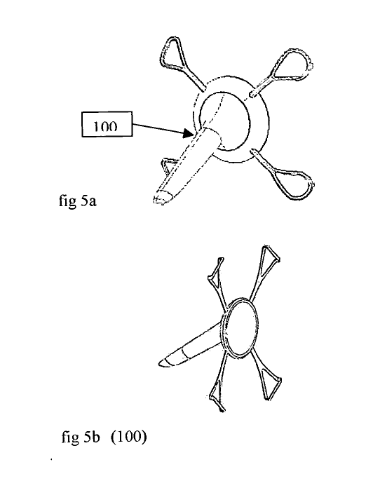

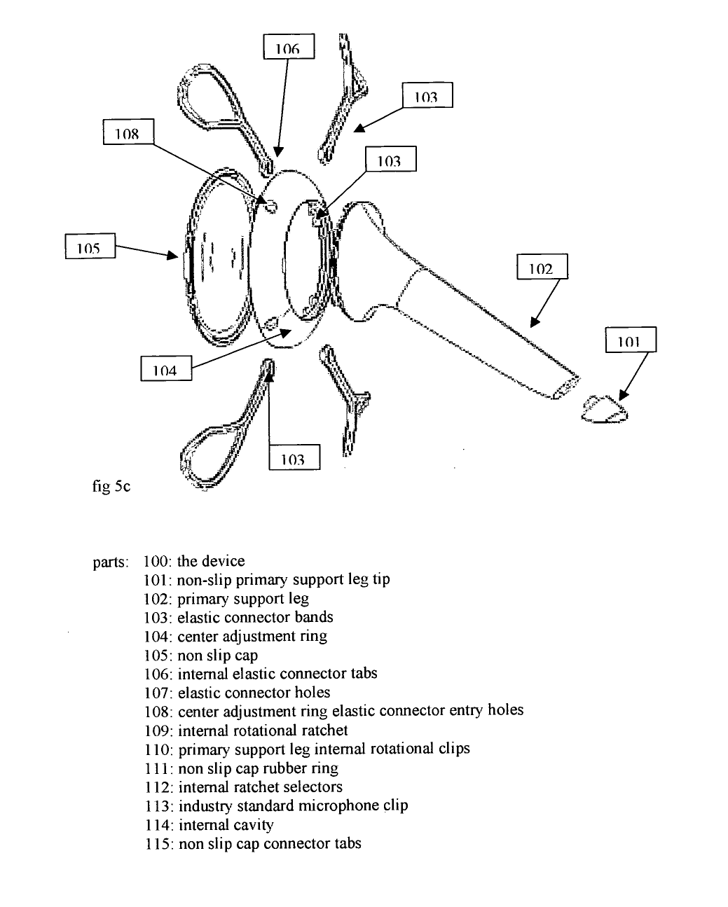

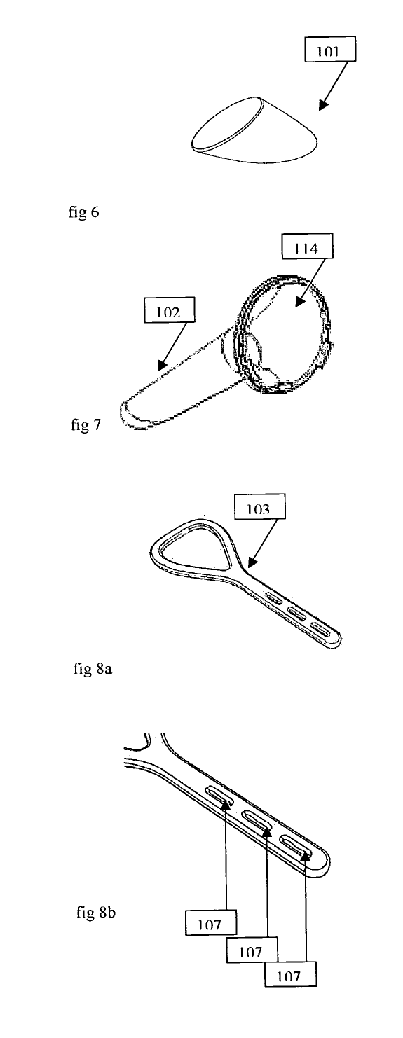

FIG. 5A illustrate the stand 100 in detail. As seen in the rear perspective views of FIG. 1A detailing the elastic connector bands 103 in its their open position and the primary support leg 101 not supporting any object held by the device.

FIG. 5B illustrate the stand 100 in detail. As seen in the front perspective views of FIG. 1A detailing the elastic connector bands 103 in its their closed position when the primary support leg 101 is supporting a tablet PC, music device, etc., held by the device.

As shown in the views of FIG. 5C the primary support leg 102 including a stopper 101. The stopper or non-slip primary support tip 101 as connected to 102 prevents the device from slipping off a horizontal surface while the non slip cap prevents objects attached to the device 100 from slipping off the device 100. Objects are secured to the device by the elastic connector bands 103 and in this case, the laptop 10, tablet PC 30 or other portable device will rest on the stand at three points, namely points A, B and C as shown in FIG. 14-17 and FIG. 1F. In addition to the overall open architecture, this bowed/curved uni-pod-type configuration promotes air circulation and cooling for the user device. Furthermore, by contacting the stand 100 at only one location, this gives additional stability to the user device. This may be especially important for table PC-type devices or laptops where the user is writing on or typing on the device.

FIG. 5c is an exploded view of the stand 100 in order to better illustrate various aspects of the stand. As seen in this figure, the primary support leg 102, as well as the pivot center adjustment ring section 104, may be formed from a number of discrete components. For example, the primary support leg 102 may comprises a main body and a pivot member 104. The pivot member 104 may be integrally formed with the main body portion 102 or may be fabricated separately and connected to the main body portion 104. The primary support leg 102 may also include one or both of a non-slip primary support leg tip and a grip member 101.

Each of these components is illustrated in detail in the accompanying figures. For instance, FIG. 7 illustrate the main body portion 102 which can be fabricated as a single component and can be connected to the pivot member of the center adjustment ring 104. As best seen in the perspective view of FIG. 1F and the front view of FIG. 1C, the main body portion 102 may include a cavity 114 formed generally by sidewalls The cavity 114 may include one or more receptacle edges 109 adapted to receive the center adjustment ring 104.

FIGS. 8a-8b illustrates the elastic connector bands 103 and elastic connector holes 107 that allow connection to the internal elastic connector tabs 106 through the elastic connector holes 107.

FIG. 9 also illustrate the connection of the internal elastic connector tabs 106 to the elastic connector bands 103 via the elastic connector entry holes 108 allowing for the connection of the elastic connector bands 103 to the center adjustment ring 104.

FIG. 9 illustrates the center adjustment ring pivot section 104 preferably includes a central pivot point 102 as connected to 104. The upper primary support leg portions 102 is desirably adjustably coupled to the central pivot 104 by an adjustment mechanism such as the internal rotational ratchet 109 and an engagement member where the internal ratched selectors 112 provides a pleasing sound, letting the user know a rotation is taking place and the device is secure.

FIG. 10 illustrates the non slip cap 105 which is desirably adjustably coupled to the center adjustment ring 104 by an series of non slip cap connector tabs 115 and when pressed upon a tablet PC, laptop, or other device the stand has a secure connection to the device via the non slip cap rubber ring 111.

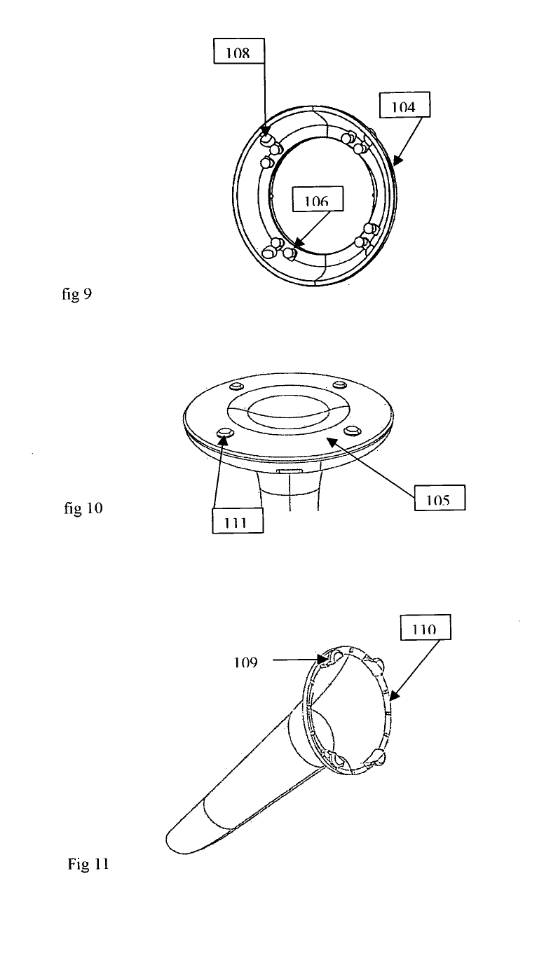

A discussion of various components and assembly of the center adjustment ring section 104 will now be presented with regard to FIGS. 11-18. FIG. 11 illustrates the pivot member or primary support leg 102 includes a receptacle or primary support leg internal rotational clips 110 adapted to receive via tension the center adjustment ring 104 securing the center adjustment ring 104 to the primary support leg internal rotational clips projections 110. the primary support leg internal rotational clips 110 hold the primary support leg 102 in place via an angular tension created as the primary support leg internal rotational clips 110 and the internal rotational ratchet 109 push themselves against the inner wall of the center adjustment ring 104 and the internal ratchet selectors 112 and preferably snaps into back into an uncompressed state, which desirably creates a clicking or other sound. This audible indicator lets the user know that the primary support leg 102 is now in the fully secure position. Once a sufficient amount of force is applied, by twisting the primary support leg around the center axis of the center adjustment ring the primary support leg moves and allows for height adjustment of the device.

FIG. 19 is a cutaway view along the 100 line of FIG. 5C. The cutaway view illustrates the relative positioning of the components of the pivot section 102. In order to rotate the open primary support leg, the pivot section 102 may be operated as follows. First, the user twists the may press the primary support leg 102 in a clockwise or counter clockwise fasjion around the cnter of rotation of the center adjustment ring 104. This pushes the internal rotational ratchet 109 against the internal ratchet selectors 112, which cause compression of internal rotational ratchet 109 while maintaining pressure of the primary support leg internal rotational clips 110 and primary support leg 102 body against the edges of the center adjustment ring 104. This results in disengagement, clicking and regagement of the of primary support leg 102 and center adjustment ring 104. The user is now able to adjust the primary support leg 102 relative to the center adjustment ring 104.

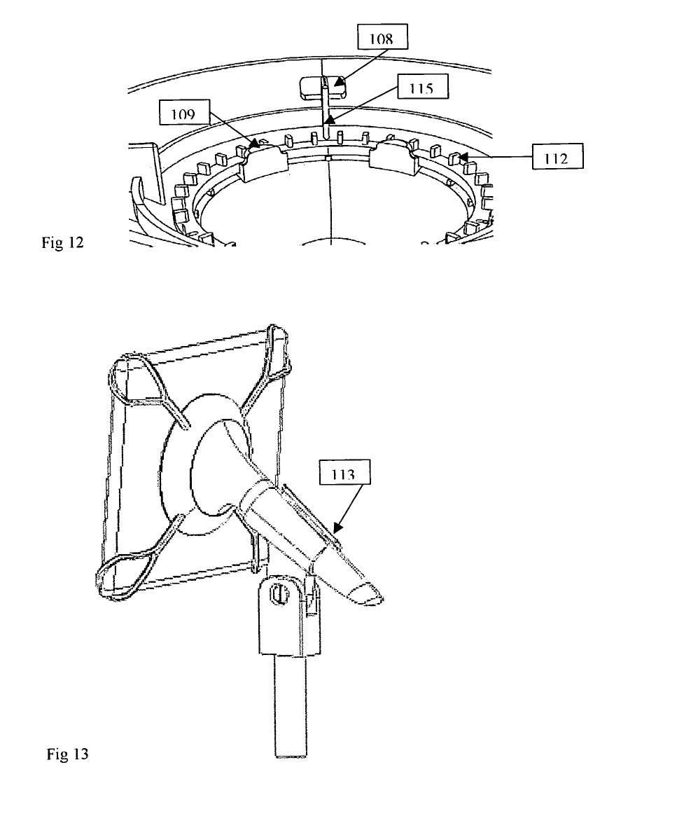

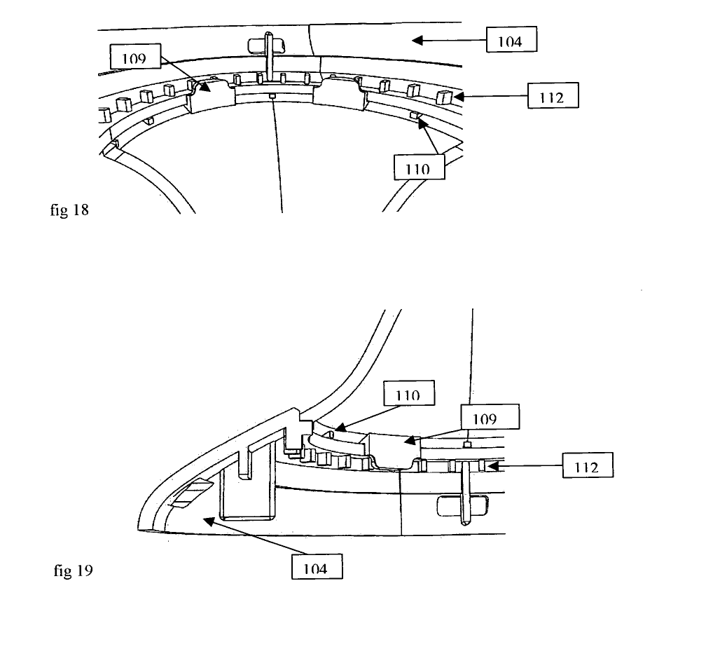

FIG. 12 illustrates also the elastic connector bands 103 being able to pass through the center adjustment ring elastic connector entry holes 108 also as detailed in FIG. 18

Also shown in these figures is an understood connection 113, to industry standard microphone clip stands FIG. 13 which enables the primary support leg 102 to rotatably move relative to the center adjustment ring 104 leg as illustrated in FIG. 13. Thus, in this arrangement, the stand 100 is not only useable on horizontal survaces but also in performance situations where desktop or horizontal surface configurations are not possible. This makes the stand 100 very beneficial for people who are performance artists and also standard users of laptop PC's and tablet PC's.

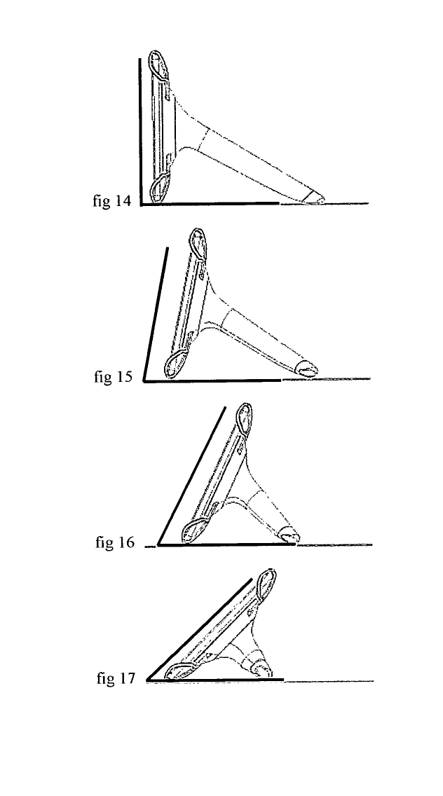

Once assembled, the stand 100 may be used in a wide range of positions and orientations. For instance, FIGS. 14-17 illustrate numerous positions when the primary support leg 102 is in a upright configuration. the primary support leg 102 is moveable along one general path or rotating plane. The stand 100 may range from a fully closed position of 0.degree. to a minimally open position shown in FIG. 15 to a substantially fully open shown in FIG. 17 with the primary support leg being nearly 165.degree.-180.degree. or any incremental range may be provided between the minimally open position to the substantially fully extended position. By way of example only, increments of 1.degree., 2.degree., 3.degree., 4.degree., 5.degree., 10.degree., 15.degree. or 20.degree. may be provided. The specific incremental positions preferably directly correspond with the spacing and placement of the series of openings 112 in the engagement member 104, thus, the user may utilize the stand in any configuration or angular mode along a horizontal surface or to rotate objects secured by the device when the device is supported in an industry standard microphone clip 113.

Although the invention herein has been described with reference to particular embodiments, it is to be understood that these embodiments are merely illustrative of the principles and applications of the present invention. For instance, the stand may or may not include audible indicators, or may incorporate visual or textural indicators in lieu of or in conjunction of the audible indicators. Furthermore, the primary support leg may be adjustable only between the fully closed and fully opened positions, or may be adjustable among any number of increments between fully closed and fully opened. All features in any of the embodiments are usable with all other embodiments presented herein. It is therefore to be understood that numerous modifications may be made to the illustrative embodiments and that other arrangements may be devised without departing from the spirit and scope of the present invention as defined by the appended claims.

CITATIONS

| Patent # | Title | Author | Issue Date |
|---|---|---|---|
| APPLICATIONS | | | |
| 11/556,970 | XDECK | David Russell | |
| | LAPTOP/BOOK- | Sparling, | |
| | HOLDER | Venice, CA ( | |
| ISSUED | | | |
| D579928 | Microphone holder | Takashi Murata | 4 Nov 2008 |
| D618222 | Equipment stand | Ryan Kallas | 22 Jun 2010 |
| 7712719 | Folding support stand | Bradley | 11 May 2010 |
| | for portable electronic | A. Derry et al | |
| | devices | | |
| D474661 | Rubber strap wrench | Wu Sheng | 20 May 2003 |
| | | Huang | |
| 4569108 | Closed loop-hook and | Leonard | 11 Feb 1986 |
| | elastic band fastener | M. Schwab | |
| D589962 | Combined support | Maruyama | April 2009 |
| | stand and data entry | et al. | |
| | device | | |
| D592188 | Electronic device | Huang | May 2009 |
| | holder | | |
| D592188 | Electronic device | Nicieja | 12 May 2009 |
| | holder | | |
| D603840 | Windshield mounting | Lee et al. | November |
| | assembly for handheld | | 2009 |
| | GPS device | | |
| D610587 | Adjustable stand | Bandringa | February |
| | | | 2010 |
| D616431 | Electronic device | Hijmans | May 2010 |
| | holder | | |
| D618692 | Stand for mobile video | Deutsch et al. | June 2010 |
| | devices | | |

REFERENCED BY

| Patent # | Title | Author | Issue Date |
|---|---|---|---|
| D630222 | Electronic device holder | Chung-Hung Lin | 4 Jan 2011 |
| D620941 | Folding laptop stand | Michael Stacey, | 3 Aug 2010 |
| | | Kevin Stacey | |
| D610587 | Adjustable stand | John Spencer | February |
| | | Bandringa | 2010 |
| D596875 | Guitar stand | Craig Small, Cedric | July 2009 |
| | | Liautaud | |

1. A portable support stand for supporting an electronic device the stand comprising:
a primary support leg having an elongated body includind a first end for contacting a support surface and a second end remote from the first end and the pivot member being disposed perpendicular the second end of the elongated body;
an adjustment member rotatably coupled to the pivot member of the primary support leg; and
wherein the primary support leg is operable to rotate between a slanted position perpendicular to the center adjustment ring and a full upright position

2. The portable stand of claim 1 further comprising a singular stopper having an non-slip primary support leg tip being coupled to the end of the respective primary support leg

3. The portable stand of claim 1 where in the non-slip primary support leg tip member is rotably counpled to the end of the primary support leg member is sustainably parallel to the primary support leg member

4. The portable stand of claim 1, wherein the upright position of the first ends of the primary support leg and the center adjustment ring are in contact with the support surface and the pivot section is elevated above the support surface.

5. The portable stand of claim 1 where in the pivot member includes a primary engagement member and the center adjustment ring adjustably coupled to the primary support leg to lock the adjustable primary support leg in the upright or alternative slanted positions and to permit movement of the primary support leg between the upright or slanted positions.

6. The portable stand of claim 5 further comprising a tension device between the center adjustment ring and the center adjustment ring at the points of the internal rotational ratchet, the internal ratchet selectors and the primary support leg internal rotational clips

7. The portable stand of claim 1 wherein the adjustable primary support leg includes means for producing an audible indicator to identify when the adjustable primary support leg is in the upright or slated positions.

8. The portable support stand of claim 1, wherein the primary support leg has a fixed length

9. The portable support stand of claim 1, wherein the primary support leg is distributed in a circular arrangement about the central point of rotation to the center adjustment ring

9a. The portable support stand of claim 1, wherein the primary support leg has a fixed diametere and capable of sliding in a parallel nature or being clipped into an industry standard microphone clip

10. The portable support stand of claim 9, where in the internal ratchet selectors in plurality of first connection members of the center adjustment ring are receptacles and at least one connection member compromises at least one projection perabe to reasonably engage at least one respective connection members

11. A portable support stand for supporting an electronic device, the stand compromising:
a series of rubber members having an elongated stretchable body including a first end for coupling the center adjustment ring to a second remote end from the first; and a first engagement member coupled to the object to be held in the stand about a corner tention point adjustably operable to relasability from the center adjustment ring when chosen and;
is in a state when at least one of the first connection members is securely coupled to at least one of the first connection members of the center adjustment ring of the first engagement member so that the elastic connector bands are able to secure objects placed in the stand to the primary support leg

12. The portable support stand of claim 11, wherein the rubber members, have a plurality of receptacles of least one connection members comprises at least one projection oberable to enage one respective connection members in the center adjustment ring.

13. The portable support stand of claim 11, wherein the rubber members, have a plurality of connetions to the object being held in the device creating a tripod configuration between the primary support leg and a support surface

14. The portable support stand of claim 11, has a cover over the elastic connector bands securing the primary support leg to the object being held in the stand creating a non slip surface parallel to the primary support leg and the center adjustment ring
